(19) United States
(12) Patent Application Publication
(10) Pub. No.: US 2014/0350873 A1
(43) Pub. Date: Nov. 27, 2014

(54) METHOD FOR GENERATING A SIGNAL INDICATING AN OSCILLATION IN AN ELECTRICAL ENERGY SUPPLY NETWORK

(71) Applicant: SIEMENS AKTIENGESELLSCHAFT, Muenchen (DE)

(72) Inventors: Andreas Litzinger, Fuerth (DE); Stefan Piel, Essen (DE)

(21) Appl. No.: 14/365,111

(22) PCT Filed: Dec. 16, 2011
(86) PCT No.: PCT/EP2011/073071

§ 371 Date: Jun. 13, 2014

(51) Int. Cl. G01R 21/133

(52) U.S. Cl. CPC G01R 21/133
USPC 702/60

(57) ABSTRACT

A method provides the operating personnel of a control center of an electrical energy supply with information about any oscillations that have occurred in an energy supply network. A signal indicating an oscillation of an electrical variable in an electrical energy supply network is generated. A state variable characterizing an oscillation state of the electrical variable is calculated from measured values of current and/or voltage indicators. If an oscillation exists, an amplitude characteristic value indicating the amplitude of the state variable and a damping characteristic value indicating a damping of an oscillation of the state variable are determined. The position of a particular value pair containing an amplitude characteristic value and an associated damping characteristic value is compared with hazard ranges, which are present in a value range and indicate a particular hazard level of the oscillation in the energy supply network. The signal indicating the oscillation is output.

The invention relates to a method for generating a signal indicating an oscillation in an electrical energy supply network.

In order to ensure the smooth running and safe operation of electrical energy supply networks, measurement values that are characteristic of the network state are monitored in network control centers in order to determine whether the energy supply network is in the proper operating state thereof or in a critical state. For this purpose, measurement values of electrical variables such as current, voltage and power are detected at selected measuring sites of the energy supply network by means of suitable transducers and typically are fed in digital form to the network control center for evaluation and observation. In order to ensure a chronological relation of the individual measurement values to one another, the measurement values recorded typically have “time stamps”, that is, time of day information added to them, indicating the time at which the measurement values were recorded. Time stamps of this type can be issued with an accuracy of one millisecond, for example.

One form of a critical operating state of an electrical energy supply network is “power swings” (simply referred to here as “oscillations”). Such oscillations arise, for example, in the presence of sudden load changes or changes to the structure of the electrical energy supply network (for example, through the switching on or off of relatively large network components).

When this occurs, the generators at the infeed points of the electrical energy supply network must adjust to the new load situation. This typically occurs in the form of a damped oscillation, with a frequency of a few Hertz, until the new operating point of the electrical energy supply network has stabilized. Oscillating current and voltage states are produced in the energy supply network by the transient response behavior of the generators and this can have different effects on the energy supply network and the electrical components thereof (e.g. conductors, cables, transformers). Whereas damped oscillations of relatively low amplitudes in the energy supply network die down relatively quickly and can therefore be accepted, weakly damped or even self-escalating oscillations, in particular, represent a highly critical state of the energy supply network which can easily lead to failures and disconnections of relatively large network sections. Furthermore, due to suddenly changing network structures in the case of the failures of individual network sections, overloading of still functional sections of the electrical energy supply network can take place, which can result in cascading switching-off events, even to the extent of a blackout. Therefore, such oscillations which are to be classified as critical must be signaled immediately to the control center operating personnel of the energy supply network.

As the number of measuring sites increases and with shorter sampling intervals for the recording of the measurement values, the number of measurement values to be monitored by the operating personnel in network control centers has risen rapidly in recent years and will probably undergo a further increase in future. In particular, as energy supply networks are configured into “smart grids”, measurement values arise in numbers which exceed the measurement value count in conventional monitoring systems for energy supply networks by whole orders of magnitude. Measurement values are recorded, for example, with phase-indicating measuring devices or “phasor measurement units (PMU)” as complex current or voltage indicators and include information concerning the amplitude and phase angle of the variable to be measured at the respective measuring site of the electrical energy supply network. Phasor measurement values of this type are recorded at high sampling rates in order, for example, to be able to recognize load flows and possible network oscillations more accurately and if needed to introduce suitable countermeasures to avert unstable states as they make their presence felt. An exemplary method with which, based on phasor measurement values through continuous adjustment of parameters of a mathematical calculation model, the presence of oscillations in an energy supply network can be concluded is known from the European patent specification EP 1489714 B1.

Due to the large number of measurement values that can be represented and the consequent multiplicity of possible operating states of the electrical energy supply network to be overseen by the operating personnel, the question arises as to which deviations from the stable operating state must be indicated as alarm signals (e.g. in the form of notifications on a workstation of the control center). From this comes the requirement that, firstly, the stable and proper operation of the energy supply network must be assured at all times and, secondly, that the frequency and content of the alarm signals must be selected such that sufficient information concerning the prevailing network state is given to the operating personnel, but without placing excessive demands on the personnel with too frequent alarms and/or too high a level of detail in the information made available with the alarm signals.

Conventional systems for recognizing oscillations in energy supply networks typically operate with a simple threshold system. Particular variables (e.g. frequency or amplitude of measured current, voltage or power profiles) are evaluated with regard to a threshold value and, in the event that a threshold value is exceeded, an alarm signal is triggered. It is then left to the operating personnel to gather the information necessary for assessing the severity of the particular hazard condition and to judge whether the applicable, possibly network-stabilizing, measures are required or not.

It is therefore an object of the invention to make information available in a suitable manner and form to the operating personnel in a control center of an electrical energy supply network concerning any oscillations occurring in the energy supply network and thus to enable the operating personnel to conduct the reliable operation of the energy supply network.

This object is achieved according to the invention by a method for generating a signal indicating an oscillation of an electrical variable (e.g. current, voltage, power, impedance) in an electrical energy supply network, wherein current and/or phasor voltage measurement values are recorded synchronously at least at one measuring site in the electrical energy supply network by means in each case of a phasor measuring device. The current and/or phasor voltage measurement values are transmitted to the control center monitoring the energy supply network; the control center system calculates a state variable characterizing an oscillation state of the electrical variable (e.g. current, voltage, power, impedance) from current and/or phasor voltage measurement values associated with each other and investigates a profile of the state variable with regard to an existing oscillation in the energy supply network. If an oscillation of the state variable exists, an amplitude characteristic value indicating an amplitude of the profile of the state variable and a damping characteristic value indicating a damping of an oscillation of the profile of the state variable are determined by the control center system. Value pairs consisting of an amplitude characteristic value and an associated damping characteristic value are compared with hazard ranges present in a value range which indicate a particular hazard level of the oscillation in the energy supply network, while determining a hazard parameter and the signal indicating the oscillation is output depending on the hazard parameter.

Using the method according to the invention, a multi-stage alarm system can be realized in a relatively easy manner, since the relevant signal which is output and indicates the oscillation is output depending on the respective hazard level that has been determined. By this means, together with the signal indicating the oscillation, the operating personnel are also directly given differentiated information concerning the hazard associated with the existing oscillation.

An advantageous embodiment of the method according to the invention provides that the state variable indicates an active power level present at a measuring site in the energy supply network. Alternatively thereto, it can also be provided that the state variable indicates a phase angle difference which signifies a phase angle enclosed between phasor voltage measurement values, wherein the phasor voltage measurement values have been recorded synchronously at two different measuring sites in the energy supply network. The embodiments described represent state variables which are particularly suitable for assessing any oscillation that is present.

According to a further advantageous embodiment of the method according to the invention, it is also provided that the damping characteristic value is determined depending on the existing frequency of the state variable.

By this means, the damping characteristic value can be adapted particularly well to the respective existing oscillation situation. The damping characteristic value can be determined, for example, according to the following equation:

$$ξ = - 100 \frac{α}{\sqrt{{α}^{2} + {ω}^{2}}} ,$$

where ξ is the damping characteristic value given as a percentage, α represents the damping, given in units of 1/s, of an exponentially decaying (or increasing) oscillation and ω is the angular frequency given in 1/s. Including the angular frequency ω in the equation for the damping characteristic value gives an indication of the dependence thereof on the existing oscillation frequency of the state variable.

According to a further advantageous embodiment of the method according to the invention, it is provided that the signal indicating the oscillation is only output if the amplitude characteristic value and/or the associated damping characteristic value each exceed a pre-determined threshold value.

By this means, the output of a signal indicating the oscillation can always be suppressed if no state impairing the stability of the energy supply network is induced by the oscillation. However, in relation to a subsequent value pair, as soon as the amplitude characteristic value and/or the damping characteristic value have exceeded their respective threshold value, the signal indicating the oscillation is output accordingly.

A further advantageous embodiment of the method according to the invention also provides that the signal indicating the oscillation contains information concerning the existing frequency of the state variable, the existing amplitude characteristic value of the state variable, the existing damping characteristic value of the state variable and/or the hazard parameter.

By this means, together with the signal indicating the oscillation, the most important information can be made directly available to the operating personnel in the control center in order to assess the existing state of the energy supply network. The signal indicating the oscillation can be output, for example, as text and/or as a graphics-based message on a display apparatus of a workstation which contains the required additional information in each case.

According to a further advantageous embodiment of the method according to the invention, it is provided that the signal indicating the oscillation is output in different ways depending on the hazard parameter.

In this way, when the signal is output, the respective different hazard level can be indicated. The signals can therefore be output, for example, as a simple text message for a low hazard level, as a text message with an additional warning function (e.g. color marking, flashing) for a medium hazard level and as a text message with an additional visual and/or acoustic warning signal for a high hazard level.

A further advantageous embodiment of the method according to the invention additionally provides that the signal indicating the oscillation is only output if the hazard parameter has not undershot a pre-determined minimum value even after the expiry of a pre-determined delay period.

By this means, it can initially be verified by the control center system whether a lasting oscillation is present and the signal is output only if the oscillation endures. In this way, the operating personnel are not burdened with unnecessarily frequent alarms. The delay period can be defined as a value that is fixed or is dependent on the oscillation frequency (e.g. after expiry of a particular number of oscillation periods of the oscillation).

According to a further advantageous embodiment of the method according to the invention, it is also provided that chronological profiles of the frequency of the state variable, of the amplitude characteristic value of the state variable, of the damping characteristic value of the state variable and/or an indication of the respective hazard parameter are stored in a storage device of the control center system.

The storage of the respective chronological profiles also allows a precise retrospective analysis of the processes in the electrical energy supply network, so that any faults can be traced.

According to a further advantageous embodiment of the method according to the invention, it is provided, finally, that from the hazard parameter and an amplitude parameter dependent on the amplitude characteristic value of the state variable and from a damping parameter dependent on the damping characteristic value of the state variable, a hazard variable is calculated, the profile of which is stored in a storage device of the control center system.

In this way, the respective hazard level of an oscillation can be stored for later analysis, not only as a discrete value according to the respective hazard range, but using the amplitude parameter and the damping parameter as a semi-continuous value within the respective hazard range. The linking of the amplitude and damping parameters is preferably chosen so that a value of between 0 and 1 can be achieved. If this value is added to the value of the respective hazard range, the result is a semi-continuous profile of the hazard variable which has a discontinuous profile only at the transition sites between two hazard ranges.

The invention will now be described in greater detail by reference to an exemplary embodiment. In the drawings:

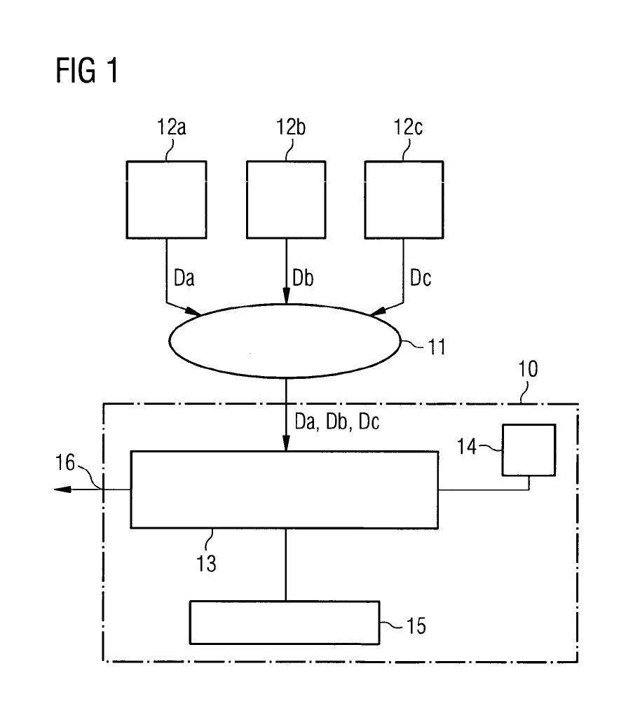

FIG. 1 is an exemplary embodiment of an automation system for monitoring an electrical energy supply network;

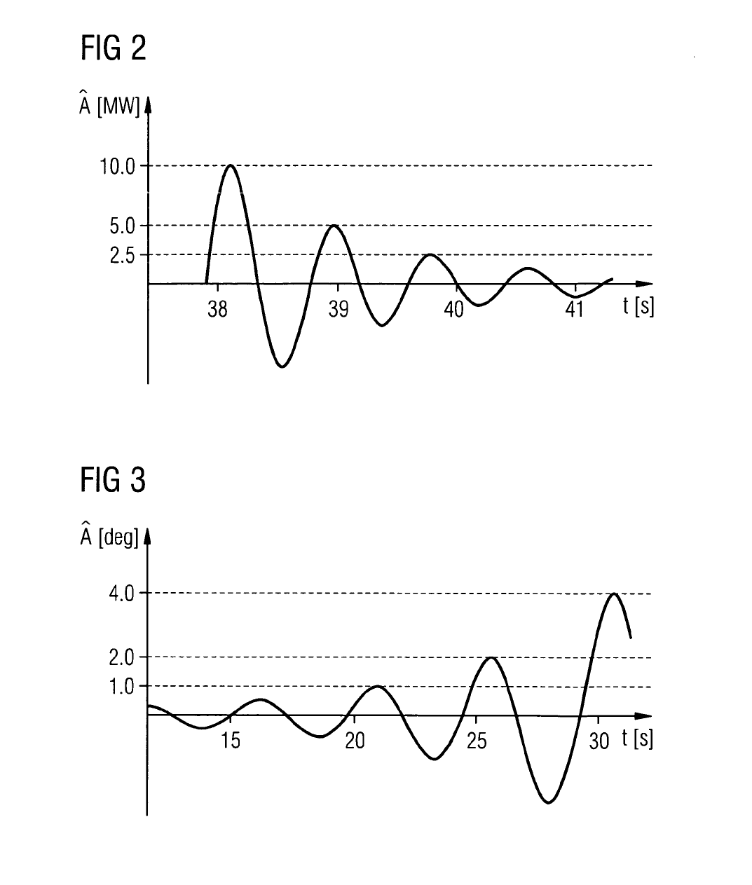

FIG. 2 is a profile over time of a state variable in the form of an active power level;

FIG. 3 is a profile over time of a state variable in the form of a phase angle difference; and

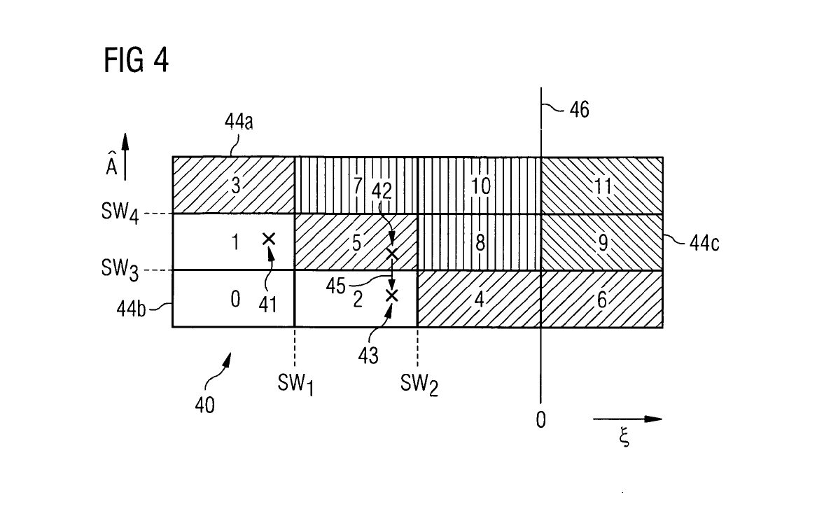

FIG. 4 is a diagram for determining the respective hazard level of an oscillation.

FIG. 1 shows an arrangement with a control center system 10, for example, a data processing device in a network control center which is connected via a data transmission network 11 to three phase-indicating measuring devices 12a, 12b, and 12c. The phase-indicating measuring devices 12a-c are, for example, “Phasor Measurement Units” (PMU) which detect current and/or voltage measurement values at measuring sites of an energy supply network (not shown in detail in FIG. 1) and therefrom generate corresponding current and/or phasor voltage measurement values. A phasor measurement value here represents a measurement value which can be entered in a complex number plane and which comprises an indication of the existing amplitude and the existing phase angle of the respective variable (in this case, current or voltage). The phasor measurement values are transmitted via the data transmission network 11 together with an indication of the respective measuring time point in the form of data sets Dₐ, D_{b} and D_{c} to the control center system 10. The number of three phasor measuring devices was selected purely by way of example in the exemplary embodiment according to FIG. 1, but naturally, configurations of arrangements with as many phasor measuring devices as desired are possible.

In the following description, it will be assumed that the phasor measuring device 12a is configured for measuring phasor current measurement values and phasor voltage measurement values and accordingly transmits, in its data sets Dₐ, a phasor voltage measurement value and an associated phasor current measurement value to the control center system 10. The phasor measuring devices 12b and 12c are configured to record phasor voltage measurement values and accordingly transmit data sets D_{b} and D_{c} to the control center system 10, each containing a phasor voltage measurement value.

The control center system 10 comprises an evaluating device 13 which is also connected to a configuration device 14 and a storage device 15. The control center system can also output a signal indicating an oscillation via a signal output 16 to an operating device of the network control center (e.g. a workstation with a display) (not shown in FIG. 1). The operating device can be either an external device or an integral component of the control center system 10.

The arrangement according to FIG. 1 can be operated, for example, as follows:

The control center system 10 evaluates the data sets Dₐ, D_{b}, and D_{c} received from the measuring devices 12a-c and thus processes the transmitted current and phasor voltage measurement values. Since the data sets Dₐ, D_{b}, and D_{c} also each contain the respective measuring time points, the control center system 10 can also determine the relevant measuring time point for each phasor measurement value.

The control center system 10 makes the phasor measurement values available to the evaluating device 13 so that said evaluating device can access the relevant phasor measurement values. The control center system 10 also stores the phasor measurement values in the storage device 15 in order to be able to make the values available for later evaluation, if needed.

From current and/or phasor voltage measurement values which belong together chronologically, the evaluating device 13 determines a state variable characterizing an oscillation state of the electrical energy supply network. The state variable can be, for example, an active power level or a phase angle difference. For the active power level, current and phasor voltage measurement values measured at a measuring site in the energy supply network are used; the active power level is determined as the product of a phasor voltage measurement value and a chronologically associated phasor current measurement value. For example, the voltage and phasor current measurement values from the phasor measuring device 12a and contained in the data set Dₐ can be used for this purpose. For the phase angle difference, synchronously measured phasor voltage measurement values measured at two different measuring sites in the energy supply network are compared with one another with regard to the proportion thereof giving the phase angle, and the phase angle difference is calculated. For example, for this purpose, the phasor voltage measurement values which are detected by the phasor measuring devices 12b and 12c and are transmitted to the control center system 10 with the data sets D_{b} and D_{c} can be used.

Using the evaluating device 13, the control center system 10 can either calculate one of the two state variables or both state variables and investigate these variables with regard to the presence of an oscillation in the electrical energy supply network. Furthermore, the respectively calculated state variable (e.g. in the form of the phase angle difference or the active power level) can be stored for later analysis in the storage device 15.

In order to investigate the state variable with regard to an oscillation present in the energy supply network, the necessary current and phasor voltage measurement values for calculating the state variable are accumulated over pre-selected time periods. When the data is complete, these values are transformed using, for example, a Fast Fourier Transform (FFT) or a Discrete Fourier Transform (DFT), into the frequency range in order possibly to identify the frequencies that are characteristic for the oscillation processes that are to be detected. Since a plurality of frequencies (“modes”) can be excited, the evaluating device can identify and calculate a plurality of modes simultaneously. The maximum number of modes to be expected and the typical frequency ranges thereof can be defined in the configuration device 14 by the operating personnel.

For each excited frequency identified during the investigation, the existing value of the time-variable amplitude in the form of an amplitude characteristic value and the current value of a damping factor in the form of a damping characteristic value are calculated. Depending on the excited frequency, measuring must take place over a relatively long period in order to be able to determine unambiguously the amplitude characteristic value and the damping characteristic value. In order to determine the damping characteristic value, the following equation is made use of by the evaluating device,

Â(t)˜exp(−αt),

where Â(t) is the time-variable amplitude (amplitude characteristic value) of the oscillating state variable and α is the damping of the oscillation in units of 1/s. Depending on the value of α, the amplitude characteristic value of the oscillating state variable can either decrease (α positive), remain constant (α=zero) or increase (α negative).

An essential parameter for the possible effects of an oscillation in the energy supply network is the damping factor ξ which is related to the oscillation frequency, identified in the following for simplification as the damping characteristic value. The damping characteristic value is dimensionless and is given below as a percentage value. The damping characteristic value can be determined, for example, according to the following equation:

$$ξ = - 100 \frac{α}{\sqrt{{α}^{2} + {ω}^{2}}} ,$$

where is the damping characteristic value given as a percentage value and ω is the angular frequency given in 1/s of the oscillating state variable. Including the angular frequency ω in the equation for the damping characteristic value gives an indication of the dependence thereof on the existing frequency of the oscillation of the state variable. The damping characteristic value therefore gives—regardless of the frequency of the oscillation—a relative measure for the amplitude change in the oscillation from any given maximum to the next. Negative damping is characteristic of an oscillation with decreasing amplitude. FIG. 2 shows, merely by way of example for illustration, a profile over time of the amplitude characteristic value Â of a state variable in the form of an active power level. The damping characteristic value of the oscillation shown is around −10%. The excited frequency detected is around 1.2 Hz. An oscillation of the state variable with a damping characteristic value of less than −5% with not too great an amplitude is typically regarded as non-critical. However, damping factors of over −3% can lead, particularly in the presence of other excitations in the energy supply network, to a rapid growth in the amplitude and must therefore be placed under special observation.

Undamped oscillations are particularly critical. A damping characteristic value of 0% corresponds to an amplitude which remains unchanged over time. Increasingly positive values are associated with an ever more steeply increasing profile of the amplitude characteristic value over time. An oscillation of this type with an increasing amplitude characteristic value Â of a state variable in the form of a phase angle difference is shown, by way of example, in FIG. 3. The damping characteristic value of the oscillations shown in FIG. 3 is around +10%. The frequency is around 0.2 Hz.

As has been made clear above, oscillations have varying hazard potentials for the energy supply network depending on the value of the amplitude characteristic value and the damping characteristic value thereof. The operating personnel of the control center system must therefore be provided the possibility, in the simplest and most transparent form possible, of recognizing the hazard potential associated with an existing oscillation in the energy supply network. In order to assess the hazard potential and thus the possible effects of an existing oscillation, a hazard parameter which characterizes the hazard potential is determined in the evaluating device 13 from the damping characteristic value ξ, taking account of the existing amplitude characteristic value Â. For this purpose, as indicated in FIG. 4, a value pair is formed from the existing value of the damping characteristic value ξ and the existing value of the amplitude characteristic value Â, and the position of the value pair is entered in a value range which is illustrated as the diagram 40 in FIG. 4.

The diagram 40 includes a pre-determined number of hazard ranges of which, purely by way of example for greater clarity, the hazard ranges 44a-c are identified in FIG. 4. The shape and position of the individual hazard ranges can be specified by the operating personnel via the configuration device 14. To each hazard range is assigned an unambiguous value of a hazard parameter. In concrete terms, in FIG. 4, for example, a hazard parameter with the value “3” is assigned to the hazard range 44a, a hazard parameter with the value “0” is assigned to the hazard range 44b and a hazard parameter with the value “9” is assigned to the hazard range 44c. The assignment of the values of the hazard parameters to the individual hazard ranges can also be carried out in the configuration device 14 by operating personnel and, with increasing hazard parameter value, should indicate an increasing hazard potential for the oscillation detected. In general, the rule applies that an increase in the values of damping parameter and amplitude parameter is associated with an increase in the values of the hazard potential. The straight line 46 in the diagram 40 gives a value 0 for the damping parameter and therefore represents the tipping point between a damped oscillation and an undamped oscillation.

In order to determine the applicable value of the hazard parameter for the respective existing oscillation, the position of the value pair of hazard characteristic value and amplitude characteristic value in the value range represented by the diagram 40 is considered. Depending on the position of the value pair in one of the defined hazard ranges, an individual hazard parameter is assigned to the existing oscillation. For example, a value pair identified with the reference sign 41, due to the position thereof in the value range, is assigned a hazard parameter with the value 1. The hazard potential associated with the oscillation characterized hereby can be assessed as low due to the relatively low value of the damping characteristic value.

A value pair identified with the reference sign 42, due to the position thereof in the diagram 40, is assigned a hazard parameter with the value 5. Due to the higher value of the damping characteristic value, a raised hazard potential is associated with this value pair as compared with the value pair 41. If the amplitude characteristic value falls during the oscillation (e.g. along the arrow 45 shown in FIG. 4) due to the damping of the oscillation, then as the value pair enters into the adjacent hazard range with the hazard parameter value 2, the hazard potential goes down.

Depending on the value of the respective hazard parameter, a different signal indicating an oscillation can now be output by the control center system 10 at the signal output 16 to the operating personnel of the control center system 10. The signal can be output, for example, as a data telegram and can include (e.g. in text form and/or in graphical form) details of the respective existing value of the amplitude characteristic value, the damping characteristic value and the hazard parameter. The signal indicating the oscillation can also be output in a different form, for example, as the value of the hazard parameter increases, in addition to the information content already addressed, the signal can also comprise further acoustic or visual warning indications (an alarm sound, flashing, a color coding). In order not to distract the operating personnel with excessively frequent signal outputs, it can also be provided that the signal is only output if a particular hazard parameter still exists even after expiry of a delay period or has not undershot a pre-determined minimum value. The value of the delay time can be set as a fixed duration or as a number of oscillation periods to be awaited—and therefore as dynamically dependent on the oscillation frequency.

It can also be provided that a signal is only output if the amplitude characteristic value and/or the damping characteristic value exceed pre-determined threshold values, for example, the threshold values SW1 to SW4 shown in FIG. 4, individually or in combination. For example, it can thus be specified that relatively harmless oscillations with hazard parameters having values of 0 (amplitude characteristic value lies below SW3 and damping characteristic value lies below SW1), 1 (amplitude characteristic value lies below SW4 and damping characteristic value lies below SW1) and 2 (amplitude characteristic value lies below SW3 and damping characteristic value lies below SW2) do not lead to the outputting of a signal. The individual threshold values can be specified with the configuration device.

The great advantage of this manner of forming the signal indicating the oscillation is that it is dependent, in a manner which is stepped as desired, on the existing amplitude characteristic value and on the existing damping characteristic value and that therefore differentiated information concerning the hazard potential associated with the existing oscillation can be output with the signal itself to the operating personnel.

If the value of the hazard parameter changes as the result of a sufficiently large change in the amplitude characteristic value and/or the damping characteristic value, the last valid output of the signal indicating the oscillation is replaced with the currently valid step.

For a higher degree of detail for a subsequent analysis of the oscillation situation, the discrete value of the hazard parameter can be supplemented by means of a semi-continuous profile of an absolute hazard variable Ψ. For this purpose, the actual value of the hazard parameter is increased by a value lying between 0 and 1 which is determined depending, firstly, on an amplitude parameter which is dependent on the amplitude characteristic value and, secondly, on a damping parameter dependent on the damping characteristic value. For example, amplitude and damping parameters can depend, as described in greater detail below, on the size of the respective exceeding of threshold values of the damping characteristic value and the amplitude characteristic value. The respective value of this absolute hazard variable Ψ can be determined, for example, according to the following relationships:

Ψ=GKG+k_{Â}·k_{ξ}

where
GKG=(discrete) value of the hazard parameter from the diagram 40;
k_{A}=amplitude parameter;
k_{ξ}=damping parameter.

The product of the amplitude parameter and the damping parameter results in a value between 0 and 1, which is added to the respective (discrete) hazard parameter and thus enables a semi-continuous profile of the absolute hazard variable. Only at the transitions from one hazard parameter to another (e.g. along the arrow 45 in the diagram 40) does the profile of the absolute hazard variable have discontinuous jumps.

The values for the amplitude parameters and damping parameters can be determined, for example, as follows:

$${k}_{\hat{A}} = \frac{\hat{A} - {\hat{A}}_{SW 4}}{\hat{A}} for \hat{A} \geq {\hat{A}}_{SW 4}$$

$${k}_{\hat{A}} = \frac{\hat{A} - {\hat{A}}_{SW 3 n}}{{\hat{A}}_{SW 4} - {\hat{A}}_{SW 3}} for {\hat{A}}_{SW 3} \leq \hat{A} < {\hat{A}}_{SW 4}$$

$${k}_{\hat{A}} = \frac{\hat{A}}{{\hat{A}}_{SW 3}} for \hat{A} < {\hat{A}}_{SW 3}$$

$$and \text{:}$$

$${k}_{ξ} = \frac{ξ}{ξ - {ξ}_{SW 2}} for ξ \geq 0$$

$${k}_{ξ} = \frac{ξ - {ξ}_{SW 2}}{- {ξ}_{SW 2}} for {ξ}_{SW 2} \leq ξ < 0$$

$${k}_{ξ} = \frac{ξ - {ξ}_{SW 1}}{{ξ}_{SW 2} - {ξ}_{SW 1}} for {ξ}_{SW 1} \leq ξ < {ξ}_{SW 2}$$

$${k}_{ξ} = \frac{{ξ}_{SW 1}}{ξ} for ξ < {ξ}_{SW 1}$$

The respective indices SW1 to SW4 relate to the values of the amplitude characteristic value or the damping characteristic value at the respective threshold value (see FIG. 4).

The absolute hazard variable calculated in this way is indicated and stored as a function of time together with the remaining parameters of the oscillation. By this means, the display and evaluation of the respective current value of the absolute hazard variable in context with the associated detailed data during operation (‘online’ mode) and in the setting of a later analysis (‘offline’ mode) are enabled.

The manner and means of forming a signal indicating an oscillation as described has the advantage of the greatest possible sensitization of the operating personnel of control center systems to recognizing and precisely assessing oscillations by suitable detailing of the information made available with a signal. This is achieved, firstly, by means of a hazard parameter indicating the hazard level in relatively fine steps and, secondly, by sufficient detailing of the parameters describing the hazard level and indicating in advance the fundamental direction for implementing possible measures.

1-10. (canceled)

11. A method for generating a signal indicating an oscillation of an electrical variable in an electrical energy supply network, which comprises the following steps of:
synchronously recording current and/or phasor voltage measurement values at least at one measuring site in the electrical energy supply network by means of a respective phasor measuring device;
transmitting the current and/or phasor voltage measurement values to a control center system monitoring the energy supply network;
calculating, via the control center system, a state variable characterizing an oscillation state of the electrical variable from the current and/or phasor voltage measurement values;
investigating a profile of the state variable with regard to an existing oscillation in the energy supply network by the control center system and, given an existence of an oscillation, carrying out by the control center system the further steps of:
determining an amplitude characteristic value indicating an amplitude of the profile of the state variable;
determining a damping characteristic value indicating a damping of the oscillation of the profile of the state variable;
comparing a position of a respective value pair containing the amplitude characteristic value and the damping characteristic value with hazard ranges present in a value range which indicate a particular hazard level of the oscillation in the energy supply network while determining a hazard parameter; and
outputting the signal indicating the oscillation, depending on the hazard parameter.

12. The method according to claim 11, wherein the state variable indicates an active power level present at the measuring site in the energy supply network.

13. The method according to claim 11, wherein the state variable indicates a phase angle difference which signifies a phase angle enclosed by the phasor voltage measurement values, wherein the phasor voltage measurement values have been recorded synchronously at two different measuring sites in the energy supply network.

14. The method according to claim 11, which further comprises determining the damping characteristic value in dependence on an existing frequency of the state variable.

15. The method according to claim 11, which further comprises only outputting the signal indicating the oscillation if the amplitude characteristic value and/or the damping characteristic value each exceed a respective pre-determined threshold value.

16. The method according to claim 11, wherein the signal indicating the oscillation contains information concerning an existing frequency of the state variable, an existing amplitude characteristic value of the state variable, an existing damping characteristic value of the state variable and/or the hazard parameter.

17. The method according to claim 11, which further comprises outputting the signal indicating the oscillation in different ways depending on the hazard parameter.

18. The method according to claim 11, which further comprises only outputting the signal indicating the oscillation if the hazard parameter has not undershot a pre-determined minimum value even after an expiry of a pre-determined delay period.

19. The method according to claim 11, which further comprises storing chronological profiles of a frequency of the state variable, of the amplitude characteristic value of the state variable, of the damping characteristic value of the state variable and/or an indication of the respective hazard parameter in a storage device of the control center system.

20. The method according to claim 11, which further comprises:
calculating an absolute hazard variable from the hazard parameter and an amplitude parameter dependent on the amplitude characteristic value of the state variable and from a damping parameter dependent on the damping characteristic value of the state variable; and
storing a profile of the absolute hazard variable in a storage device of the control center system.
